(19) United States
(12) Patent Application Publication
(10) Pub. No.: US 2006/0240680 A1
(43) Pub. Date: Oct. 26, 2006

(54) Substrate processing platform allowing processing in different ambients

(75) Inventors: Yoshitaka Yokota, San Jose, CA (US); Kirk Moritz, Foster City, CA (US); Kai Ma, Mountain View, CA (US); Wen Chang, Sunnyvale, CA (US); Anastasios Parasiris, Santa Clara, CA (US); Rohit Sharma, Santa Clara, CA (US); Agus Tjandra, San Jose, CA (US); Vedapuram Achutharaman, San Jose, CA (US); Sundar Ramamurthy, Fremont, CA (US); Randhir Thakur, San Jose, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: APPLIED MATERIALS, INC.

(21) Appl. No.: 11/114,250

(22) Filed: Apr. 25, 2005

(51) Int. Cl. H01L 21/00

(52) U.S. Cl. 438/800

(57) ABSTRACT

A semiconductor wafer processing system including a factory interface operating at atmospheric pressure and mounting plural wafer cassettes and plural wafer processing chambers connected to the factory interface through respective slit valves. A robot in the factory interface can transfer wafers between the cassettes and the processing chambers. At least one of the processing chambers can operate at reduced pressure The processing chamber may be a rapid thermal processing chamber including an array of lamps irradiating a processing volume through a window. The lamphead is vacuum pumped to a pressure approximating that in the processing volume. A multi-step process may be performed with different pressures. The invention also includes a wafer access port of a thermal processing chamber which can flow an inert gas in outside of the slit valve to thereby form a gas curtain outside of the opened slit to prevent the out flow of toxic processing gases.

### FIELD OF THE INVENTION

The invention relates generally to semiconductor processing equipment. In particular, the invention relates to a platform to which multiple processing chambers are attached.

### BACKGROUND ART

Much of modern commercial semiconductor processing is performed in single-wafer processing chambers attached to a central transfer chamber through respective vacuum slit valves. The transfer chamber and much of the associated control and vacuum equipment is referred to as a platform, which can be combined with different types of processing chambers. Different processing chambers allowing sputtering, etching, chemical vapor deposition (CVD), and rapid thermal processing (RTP). The transfer chamber is held at a reduced pressure to prevent contamination and perhaps oxidation of the wafers between processing steps and to allow the processing chambers to always be held at reduced pressure, which for etching may be in the milliTorr range and for sputtering in the microTorr range. A robot arm within the transfer chamber can transfer wafers from a wafer cassette in a vacuum load lock to any of the processing chambers and can also transfer wafers between chambers for different processing steps.

Although multi-chamber platforms including a vacuum transfer chamber are very effective, they are large and relatively expensive. Further, they occupy large amounts of floor space in very expensive clean rooms. That is, they have a large foot print. Also, their size requires that the platform and its chambers be shipped separately with much of the plumbing and wiring disconnected. As a result, even if the system has been assembled and tested at the equipment factory, it needs to be disassembled for shipment and reassembled and retested at the wafer fabrication line. Accordingly, the lead time between ordering a system and putting it into production may be significantly long. Therefore, in some applications, may and simpler platforms may be useful.

Rapid thermal processing (RTP) is one application not greatly benefitting from a vacuum transfer chamber. In RTP, an array of high-intensity lamps can quickly heat a wafer to a high temperature, for example, 700° C. or even above 1250° C., to thermally activate a process such as annealing or oxidation. After a relatively short time at the elevated temperature, the lamps are turned off and the wafer quickly cools, thereby reducing the thermal budget. RTP is typically performed at atmospheric pressure or at a relatively relaxed vacuum, for example, in the Torr range. Tam et al. in U.S. Patent Application Publication 2003/0186554, incorporated herein by reference in its entirety, describe an RTP platform of the general sort available as the Vantage platform from Applied Materials, Inc. of Santa Clara, Calif. An RTP system 10 illustrated in the orthographic view of FIG. 1 includes two RTP chambers 12, 14 mounted on a common frame 16, which also mounts respective controllers 18, 20 and a gas supply system\] 22 and exhaust pumps. The two RTP chambers 12, 14 are connected through respective slit valves to a factory interface 26, which may form a wall between the mechanical equipment of the platform and the clean room. Operators within the alley load cassettes 30, such as FOUP boxes, carrying multiple wafers 32 supported on shelves within the cassettes 30, into two cassette positions in the factory interface 20. A single unillustrated robot in the factory interface 26 can transfer wafers 32 from either of the loaded cassettes 30 into either of the RTP chambers 12, 16 for processing and then transfers them back to the cassettes 30 after processing. This operation allows nearly continuous processing by the two RTP chambers 12, 14 while the operator is loading and unloading cassettes 30 to and from the factory interface 26.

The illustrated system 10 does not include a vacuum load lock for the cassettes and the RTP chambers 12, 14 are opened to the atmosphere of the clean room between wafer cycles. The RTP chambers 12, 14 conventionally used with this system are not vacuum pumped but operate at substantially atmospheric pressure. Processing gases are sufficiently pressurized to be forced into an exhaust line. This limitation simplifies the platform since there is no vacuum pump and the high-intensity lamps can operate at atmospheric pressure with minimal pressure differential across the lamp window. The system is small enough that the system mounted on the frame 16 may be shipped intact and quickly installed at the fab line adjacent the factory interface 26.

Tam et al. address the problem in an atmospheric factory interface of preventing contaminants in the clean room from flowing into the chamber during wafer transfer. They maintain a slightly positive pressure of an inert gas within the chamber when the slit valve is opened so that the inert gas flows into the factor interface rather than the atmosphere of the clean room flowing into the chamber.

### SUMMARY OF THE INVENTION

A multi-chamber substrate processing platform includes a factory interface operating at atmospheric pressure for holding substrate cassettes and a plurality of processing chambers connected to the factory interface through respective valved slits. A robot can transfer substrates between the cassettes and the processing chambers. At least one of the processing chambers can operate at reduced pressures, for example, less than 200 Torr or be capable of vacuum pumping to remove processing gases, especially toxic gases.

The processing chamber may be configured for rapid thermal processing (RTP) including an array of incandescent lamps directing radiant energy through a window to the vacuum process chamber holding the substrate being thermally processed. A thermal transfer gas, for example, of helium is supplied into a lamp head cavity enclosing the array and is vacuum pumped to a reduced pressure, preferably approximating the pressure within the vacuum process chamber. A single vacuum pump can pump the lampheads of multiple RTP chambers.

The invention includes a multi-step process to be performed in an RTP chamber, especially one vented to atmosphere for substrate transfer, in which different steps are performed at different processing pressures and temperatures.

One aspect of the invention includes a manifold adjacent an RTP chamber for mixing oxygen and hydrogen that are metered in a gas panel and distributed to the manifold by separate gas lines.

A further aspect of the invention includes a gas sheet of inert gas that may be formed on the port between the factory interface and the slit valve, particularly when the slit valve is opened, to prevent the back flow of processing gas into the factory interface.

### BRIEF DESCRIPTION OF THE DRAWINGS

FIG. 1 is an orthographic view of a conventional atmospheric pressure system platform

FIG. 2 is an orthographic view of a pressure variable system platform of one embodiment of the invention.

FIG. 3 is a schematic sectional view of one embodiment of a rapid thermal processing (RTP) chamber that may operate at reduced pressure as part of the system platform of the invention.

FIG. 4 is a schematic illustration of the gas supply plumbing within the system of FIG. 2.

FIG. 5 is an orthographic view of a port linking the factory interface to a processing chamber and including means for creating a gas sheet when the slit valve is opened.

FIG. 6 is a schematic plan view of a system platform of FIG. 3 and its operation.

FIG. 7 is a timing diagram of a multi-step thermal process enabled by the invention.

### DETAILED DESCRIPTION OF THE INVENTION

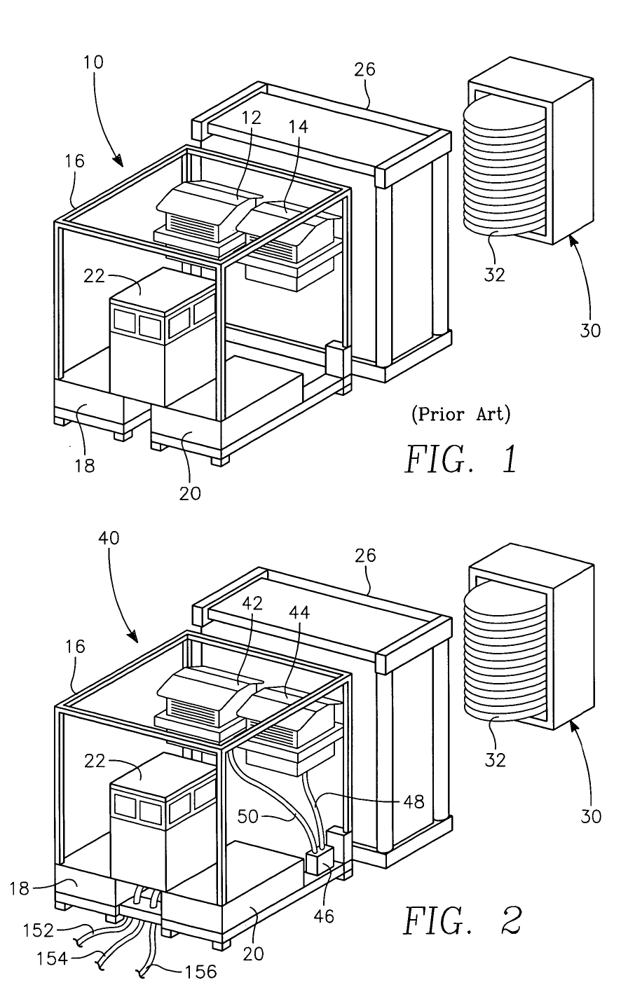

The platform of the general sort illustrated in FIG. 1 having a factory interface 26 with no load lock can be modified to a multi-chamber system 40, illustrated in the orthographic view of FIG. 2, for mixed processing ambients and having one or two rapid thermal processing (RTP) chambers 42, 44 that can be vacuum pumped to relatively low pressures and which allow the use of toxic gases. The system 40 additionally includes a vacuum pump 46 supported on the frame 16 and connected to the RTP chambers 42, 44 through respective exhaust lines 48, 50 for pumping the two RTP lampheads. The RTP chambers 42, 44 are examples of reduced-pressure chambers that can operate with internal processing pressure of less than 200 Torr. Chambers other than RTP chambers may be used with the invention, but RTP is of immediate interest. The reduced pressure may be needed during a purge of undesirable processing gases from the chamber. The low pressure necessitate additional features in the chamber and its pumps to account for the near vacuum and the large differential pressures across chamber walls.

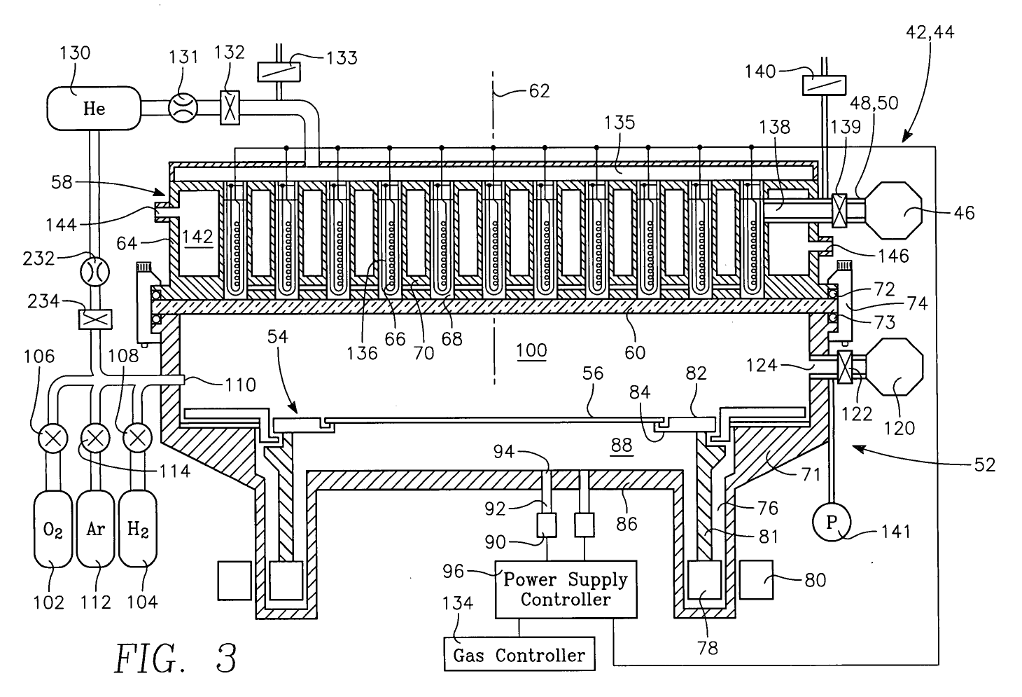

The RTP chambers 42, 44 may include features previously used only when the chamber was attached to a vacuum pumped transfer chamber. One embodiment of the reduced-pressure RTP chamber 42, 44, schematically illustrated in cross section in FIG. 3, includes a vacuum chamber 52 accommodating a wafer support 54 for supporting a wafer 56 in opposition to a lamphead 58, which radiantly heats the wafer 56 through a window 60, all of which are generally symmetrically arranged about a central axis 62. The window 60 is formed of a glassy material such as quartz. It is large and thin and cannot stand off a large pressure differential. The lamphead 58 is formed of a metallic lamp body 64 which supports a large array of high-intensity incandescent lamps 66 disposed in holes 68 that act as light pipes for directing the lamp radiation through the window 60 towards the wafer 56. The lamps 66 are typically arranged in an hexagonal close packed array but they may be additionally grouped in multiple separately controlled radial zones centered on the central axis 62 to allow a profiled intensity of the radiation.

The vacuum chamber 52 includes a main chamber body 71, which supports the window 60. O-rings 72, 73 seal the window 60 to the main chamber body 68 and the lamp body 64 when clamps 74 or other fixing means such as screws or bolts press them together. An annular channel 76 is formed in the main chamber body 71, in which is disposed a magnetic rotor 78, which can rotate about the central axis 62 in the annular channel 76. A magnetic stator 80 is driven by an unillustrated motor to rotate about the central axis 62 and is magnetically coupled through the main chamber body 71 to the magnetic rotor 78 to both support it in the vertical direction and to drive it to rotate about the central axis 62. The magnetic rotor 78 supports a tubular riser 81, which in turn supports an edge ring 82 having an annular lip 84 supporting at its tip the periphery of the wafer 56. A typical width of the lip 84 is about 4 mm. Thereby, the wafer 56 is rotated about the central axis 62, for example, at a speed of about 240 rpm. The tubular riser 81 is typically formed of silica while the edge ring 82 may be formed of silicon, silicon carbide, or silicon coated quartz. The inside of a bottom wall 86 of the main chamber body 71 underlying the wafer may be highly polished to form a black body cavity 88 below the wafer 56 for the thermal radiation emitted by the wafer 56 as the lamphead 58 radiantly heats it. An exemplary height of the black body cavity 71 is about 4.3 mm

Multiple pyrometers 90, for example, seven, are coupled by light pipes 92 disposed in holes 94 formed in the bottom wall 86 at different radial positions to receive radiation from different radial portions of the wafer 56 or edge ring 82 to measure the radial distribution of temperature or other thermal property as the edge ring 82 and supported wafer 56 rotate about the central axis 62. A power supply controller 96 receives the outputs of the pyrometers 90 and accordingly adjusts the power delivered to the incandescent lamps 66. The power is varied to control the heating rate and is further differentially supplied to the radial heating zones, for example, 13 zones across a 300 mm wafer, to improve the radial temperature distribution across the wafer 56.

A processing space 100 is formed between the window 60 and the top surface of the wafer 56, for example, having a thickness of 36 mm. A processing gas, such as a mixture of hydrogen and oxygen may be supplied from an oxygen source 102 and from a hydrogen source 104 respective mass flow controllers 106, 108 to a gas inlet 110 to the processing space 100. Oxygen and hydrogen are used for an oxidation process referred to as in situ steam generation. That is, oxygen and hydrogen react to form water vapor within a chamber held at reduced pressure of, for example, between 5 and 20 Torr. However, other processing gases may be used if the invention is applied to other production processes, such as ozone oxidation, nitridation, hydrogen annealing, and chemical vapor deposition. Typically, an inert gas such as argon is supplied from a source 112 through another mass flow controller 114 for use as a purge gas or a diluent. For gas flows which do not need to be metered, a restricted flow orifice and a valve may be substituted for a mass flow controller.

A vacuum pump 120 is connected through a valve 122 to a pump port 124 on the side of the processing space 100 to exhaust the processing gas and reaction by products and to pump the processing space 100 to a sub-atmospheric pressure. In the case of toxic or flammable gases, the pump 120 should be remote from the system 40 of FIG. 2, preferably in another room perhaps underneath the clean room that is equipped for handling and disposing the toxic or flammable gases. The prior-art RTP chambers 12, 14 connected to the atmospheric system of FIG. 1 do not require a vacuum pump but instead may rely upon pressurized process gas to drive the gas flow into an exhaust line or port and upon pressurized purge gases to remove any toxic or flammable gases from the chambers prior to wafer transfer.

A thermal transfer gas, such as helium, is supplied from a gas source 130 through a passive restricted flow orifice 131, for example, passing 50 sccm of helium, which then passes through a valve 132 and past a pressure release vent 133 to a gas manifold 135 in back of the lamp holes 68. Both the valve 132 and the pressure release vent 133 are controlled by a gas controller 134, associated with the power supply controller 90, to regulate the absolute supply and the pressure of the helium being supplied to the gas manifold 135 of the lamphead 58. Bulbs 136 of the lamps 66 loosely fit within the lamp holes 68 and porous potting material fix the backs of the bulbs 136 to the tops of the lamp holes 68. The thermal transfer gas flows from the manifold 135 into the gaps between the lamp bulbs 136 and the sides of the lamp holes 68 to promote cooling of the lamps 46.

The common lamphead vacuum pump 46 is connected through a lamphead outlet 138 and the respective exhaust line 48, 50 to the volume surrounding the bulbs 136 within the sealed chamber of the lamphead body 64 to control the pressure at the backside of the window 60 and reduce the pressure differential across the window 60. A valve 139 can block the flow on the respective exhaust hose 48, 50 and a pressure relief vent 140 can regulate the pressure on the outlet 138 and accordingly within the lamphead 58. A manometer 141 or other pressure sensor connected to the main pump port 124 measures the pressure within the process space 100. The gas controller 134 receiving the pressure signal from the manometer 141 over unillustrated electrical line and controls the two valves 132, 139 and the two pressure relief vents 133, 140 over yet other unillustrated electrical lines to suitably control the lamphead pressure.

Ideally, the pressure of the helium on the back side of the window 60 in the lamphead approximately equals the pressure of the processing or purge gases or atmosphere in the processing space 100 on the front side of the window 60 during atmospheric wafer transfer, during pump down, during processing, and during purging. If necessary, the lamphead pressure may be raised above atmospheric pressure relying upon the pressure of the helium source 130. Pressure differentials of more than 5 Torr between the lamphead 58 and the processing space 100, that is, across the window 60, should be avoided. If both chambers 42, 44 are reduced-pressure chambers, only the single vacuum pump 46 may be connected to the respective chambers 42, 44 through respective outlet ports 138, and valves 139. The gas flow controller 141 controls the various mass flow controllers, valves, vents, and pumps over unillustrated electrical lines to control the flow of the gases and the back side and front side pressures during different phases of the processing cycle.

Cooling channels 142 are formed in the lamphead body 64 to convey cooling water supplied through an inlet 144 and exhausted through an outlet 146. The cooling channels 142 surround the lamp holes 68 and thereby cool the lamps 64 with the assistance of the thermal transfer gas. Helium is used as the thermal transfer gas to increase the thermal coupling at the reduced pressures used for some RTP processes. In contrast, for atmospheric processes, helium is not required as the thermal transfer gas and an atmospheric air ambient provides adequate thermal transfer within the lamphead 58.

Thus, the reduced-pressure RTP chambers 42, 44 require a new lamphead vacuum pump 46, new processing vacuum pumps 120, plumbing for the helium from the gas panel supplying the chamber, elements not required for an atmospheric RTP chamber.

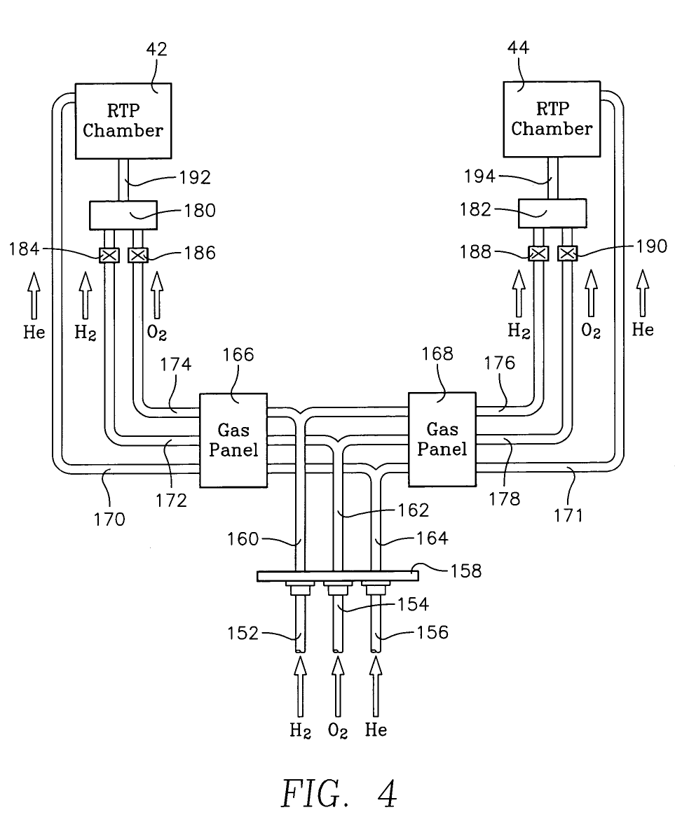

Facility gas supply lines 152, 154, 156 illustrated in FIG. 2, supply different gases, such as oxygen, hydrogen, and helium, to the system 40 2 and are detachably connected at the bottom of a gas dock plate 158 fixed to the bottom of the frame 16. Processes other than in-situ steam generation may require other gases. Nitrogen or argon may additionally be supplied as a purge gas. As schematically illustrated in FIG. 4, system gas supply lines 160, 162, 164 are connected through the dock plate 158 to respective ones of the facility gas supply lines 152, 154, 154 and are split to supply two gas panels 166, 168 associated respectively with the two RTP chambers 42, 44 and supported within the frame 16 in the area between the RTP chambers and the back of the frame 16. The gas panels 166, 168 contain the various valves, mass flow controllers and other flow control devices associated with the two RTP chambers. Helium is directly supplied from the gas panels 166, 168 to the RTP chambers 42, 44 through gas lines 170, 171. Similar direct lines would be provided for argon and nitrogen and most processing gases. Oxygen and hydrogen for in-situ steam generation, however, are supplied by gas lines 172, 174, 176, 178 to two manifolds 180, 182 associated respectively to the two RTP chambers 42, 44 and located near to them. Gas valves 184, 186, 188, 190 are located on ends of the gas lines 172, 174, 176, 178 close to the manifolds 180, 182. The oxygen and hydrogen metered by four mass flow controllers in the gas panels 166, 168 mixes in the manifolds 180, 182 and the steam-generating mixture is quickly delivered though gas inlets into the RTP chambers 42, 44. The mixing is delayed for safety reasons and to simplify the dynamics of the steam generating process.

Another drawback of the atmospheric factory interface 26 is that toxic or flammable gases used in the processing chamber may flow back into the factory interface 26 and from there directly into the clean room. However, the additional vacuum capability of the reduced-pressure chamber 42, 44 of FIG. 3 allows the processing space to be vigorously pumped after processing to more effectively remove any remnants of the undesired gases. The chamber 42, 44 is then quickly back filled with argon or other inert gas before the slit valve is opened to the atmospheric pressure of the factory interface to allow transfer of wafers.

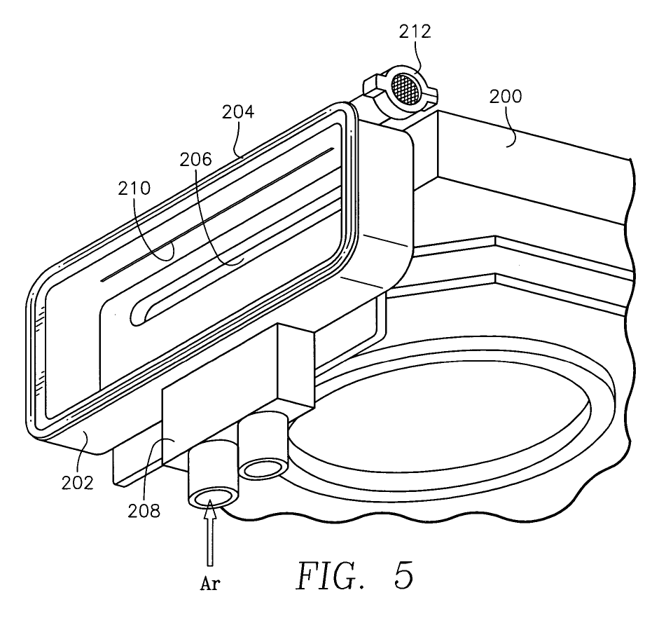

Tam et al. in the aforecited printed application disclose additional chamber purging in the presence of toxic processing gases. Another technique applicable to both atmospheric and reduced-pressure chambers creates an inert gas curtain at the chamber slit when the slit valve is opened. As illustrated in the orthographic view of FIG. 5, an RTP chamber 200 is sealed to the factory interface 26 through a port 202 having an O-ring 204 pressed to the wall of the factory interface 26 around a corresponding hole in the wall. A wafer slit 206 is formed in wall of the RTP chamber 200 to allow passage of a robot paddle and the wafer it supports. An unillustrated slit valve located within the RTP chamber 200 can close the wafer slit 206 to isolate the processing space 100 of the RTP chamber 200 from the factory interface 26 or to open the wafer slit 206 to allow wafer transfer.

An inert gas such as argon supplied from the argon source 112 through another mass flow controller or valve and restricted flow orifice and is thus selectively supplied to a gas supply manifold 208 having an unillustrated gas inlet slit to the side of the port 202 beneath and outside of the wafer slit 206. A gas outlet slit 210 is formed in the side of the port 202 opposite and parallel to and longer than the gas inlet slit fed from the gas manifold 208. The gas outlet slit 210 extends across the entire width of the wafer slit 206 and farther. An unillustrated gas exhaust manifold receives the gas from the gas outlet slit 210 and feeds it to an exhaust port 212. A separate vacuum pump or the chamber pump 120 may pump the exhaust port 212. Alternatively, a strong purge pressure may be sufficient to exhaust the gas through an exhaust line. Just before the chamber slit valve is opened when a toxic or flammable processing gas has been used, the inert gas is supplied to the gas supply manifold 208 and the valve to the associated vacuum pump is opened to thereby form a curtain of inert gas flow across the face of the opened slit 206. Thereby, any toxic or inert gas back flowing from the processing chamber 200 towards the factory interface 26 is pumped out of the system away from the factory interface 26 to be neutralized or otherwise processed or vented according to well known procedures. Furthermore, the gas curtain largely prevents the atmosphere of the clean room and factory interface and from flowing into the opened RTP chamber 200, thereby reducing contaminants in the RTP processing space. When the slit valve is closed, the gas curtain can be turned off if desired. The wafer paddle and any supported wafer may pass through the gas curtain without interrupting its flow.

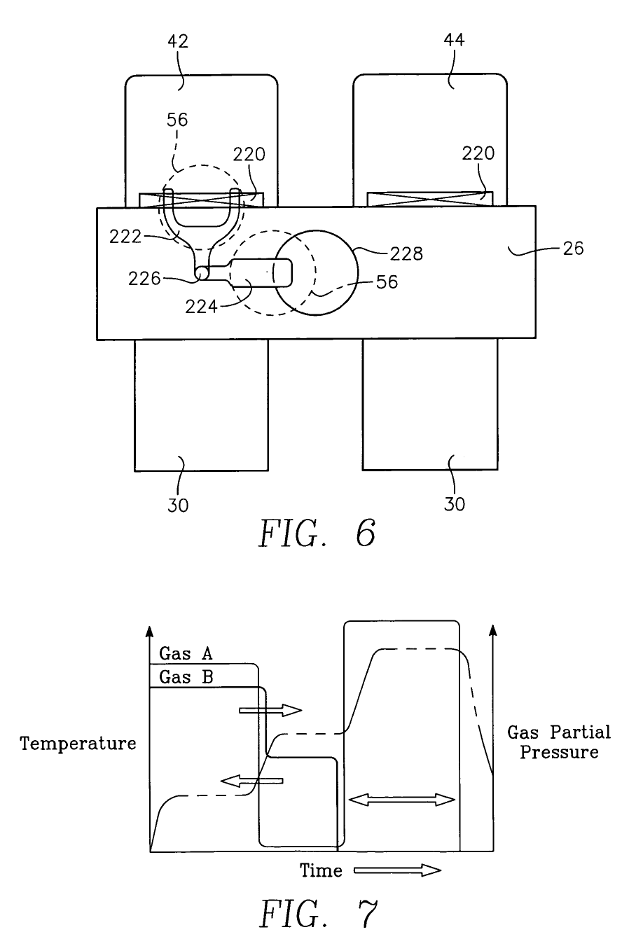

The factory interface 26 is schematically illustrated in the plan view of FIG. 6. The two RTP chambers 42, 44 are coupled to the factory interface through respective slit valves 220 included within the RTP chambers 42, 44. Respective gas shield ports 202 of FIG. 5 may be interposed between the slit valves 220 and the factory interface 26. Two wafer cassettes 30, for example, FOUPs, are selectively mounted to the factor interface 26. The cassettes 30 are typically held at or near atmospheric pressure and are in open communication with the interior of the factory interface 26 after being mounted. A two-bladed robot has a hot blade 222 and a cold blade 224, each of which can support a respective wafer 56 and which are supported and rotated by a shaft 226. The shaft 226 can rotate the blades 224, 226, can travel along a track extending along the factory interface 26, can project either blade 222, 224 into either of the two RTP chamber 42, 44 or the cold blade 224 into either of the cassettes 30, and can raise and lower to the different shelves of the cassettes 30 to transfer the wafer 56 to and from those shelves and to and from the support mechanisms of the RTP chambers 42, 44.

The factory interface also includes a cooling chuck 228 accessible by both blades 222, 224. In one mode of operation, while a wafer 56 is being thermally processed in one of the chambers 42, 44, the cold blade 224 removes an unprocessed wafer from either of the cassettes 30. At the completion of thermal processing, the slit valve 220 is opened, the hot blade 222 removes the hot processed wafer 56 from the RTP chamber 42, 44 and the cold blade immediately places the unprocessed wafer 56 in the same RTP chamber. The slit valve 220 is then closed and the RTP chamber 42, 44 begins to process the new wafer 56. The hot blade 222 places the hot processed wafer onto the cooling chuck 228 and leaves it there a sufficient time to allow it to cool to a temperature low enough for the cassettes 30, which are typically made of plastic. The cold blade 224 removes the cooled wafer 56 from the cooling chuck 228 and places it into one of the cassettes 30 and then removes an unprocessed wafer 56 from one of the cassettes 30. The process may alternate between the two RTP chambers 42, 44 with the use of a single robot and single cooling chuck.

Although a two-chamber system has found great commercial success, the inventive system may include more than two chambers served by a common factory interface.

The invention thus allows the simple atmospheric factory interface to be used for reduced pressure RTP, such as the in situ steam generation. In another example of radical oxidation processes, ozone may be used as the oxidizing gas. For safety reasons, ozone should be maintained at a pressure of less than 20 milliTorr. Other processes involving reaction of radicals typically require low pressures to increase the lifetimes of the radicals. The invention also permits the use of toxic processing gases such as NH₃ and NO₂ since the chamber may be pumped out and backfilled with N₂ before the slit valve is opened. The invention also allows a high-temperature hydrogen anneal. The use of the inventive chambers with a toxic or flammable processing gas may include a near atmospheric process with the processing gas followed by a vacuum pump down to remove the deleterious gas from the processing chamber prior to opening it to the atmospheric factory interface.

High temperature processes are facilitated by modifying the chamber 44 of FIG. 3 to allow helium to be supplied from the helium source 130 through another restricted flow orifice 232 and valve 234 selectively supplying helium the inlet port 110 of the processing space 100. At the end of high-temperature processing, for example, at reduced processing pressure, the processing gas if any is turned off and instead helium is supplied into the processing space 100 to hasten wafer cooling before the wafer is transferred to the hot blade since extremely hot wafers should not be moved or contacted by moving parts. Alternatively, helium may be supplied to the backside of the wafer 56 through conventional purge ports. On example of a high-temperature process is smoothing of a silicon surface of an SOI (silicon on insulator) wafer in a hydrogen ambient.

Other processes enabled by the reduced-pressure chamber include low-temperature oxidation, plasma-assisted oxidation, forming gas anneals, chemical vapor deposition as well as others. The reduced-pressure chamber also enables a multi-step process, such as that generally illustrated in the timing diagram of FIG. 7, in which the wafer temperature is increased in a series of steps. At the different steps, different combinations of two gases are flowed into the chamber at different chamber pressures and different wafer temperatures. For example, in the in situ steam generation, the chamber is filled with a nitrogen ambient, pumped out, and then hydrogen and oxygen is back flowed into the chamber for relatively high-temperature processing. The reduced-pressure chamber also may used for chemical vapor deposition (CVD) involving precursors which should not be vented to the factory interface. The CVD may be done in an RTP chamber with incandescent lamps, in a chamber including a scannable laser source, or in a more conventional CVD vacuum chamber with a heated pedestal and gas showerhead.

The two-chamber system of the prior art of FIG. 1 typically replicates the two chambers 12, 14 for performing the same atmospheric process. The replication increases throughput and reduces the cost of shared elements. The inventive multi-chamber system of FIG. 2 can also similarly replicate the two or more reduced-pressure chambers. However, the invention also allows the different chambers to perform different functions and to be differently configured. One chamber may be a conventional atmospheric chamber while another can operate at reduced pressure. Thereby, multiple processing steps may be performed with the same atmospheric factory interface. Examples of such combinations are: laser annealing and RTP spike annealing; spike annealing and gate oxide formation; implant annealing and surface smoothing; barrier metal annealing and dielectric densification anneal.

The invention thus allows a significant increase in the capability of a small and simple system with small increases in the complexity and size of the system.

1. A multi-chamber processing system, comprising:
a factory interface operating at substantially atmospheric pressure and capable of mounting a plurality of substrate cassettes;
a plurality of substrate processing chambers connected to said factory interface through respective valved access ports, at least one of said substrate processing chambers operating at a reduced pressure of less than 200 Torr; and
a robot mounted within said factory interface and including one or more blades capable of transferring substrates in and out of said plurality of substrate processing chambers and said substrate cassettes.

2. The system of claim 1, wherein at least one of said substrate processing chambers is a thermal processing chamber including:
a vacuum chamber including a support for a substrate;
a window sealing a side of said vacuum chamber;
an array of incandescent lamps disposed in a sealed lamp chamber on side of said window opposite said support; and
a vacuum pump capable of pumping said lamp chamber to a reduced pressure.

3. The system of claim 2, further comprising a source of helium connected to said lamp chamber.

4. The system of claim 1,
wherein two of said substrate processing chambers are respective thermal processing chambers, each including
a vacuum chamber including a support for a substrate,
a window sealing a side of said vacuum chamber, and
an array of incandescent lamps disposed in a sealed lamp chamber on side of said window opposite said support;
and further comprising:
a frame mounting said two thermal processing chambers;
a source of helium connected to each of said lamps chambers; and
a vacuum pump mounted on said frame capable of pumping both of said lamp chambers.

5. A multi-chamber processing system, comprising:
a factory interface operating at substantially atmospheric pressure and capable of mounting a plurality of substrate cassettes;
a plurality of substrate processing chambers connected to said factory interface through respective valved access ports; and
a robot mounted within said factory interface and including one or more blades capable of transferring substrates in and out of said plurality of substrate processing chambers and said substrate cassettes;
wherein at least one of said substrate processing chambers is a thermal processing chamber including
a vacuum chamber including a substrate support,
a window sealing a side of said vacuum chamber opposite said substrate support,
an array of incandescent lamps disposed in a sealed lamp chamber on side of said window opposite said substrate support, and
a vacuum pump capable of pumping said sealed lamp chamber to a reduced pressure.

6. The system of claim 5, further including a source of helium connected to said lamp chamber.

7. The system of claim 5, further comprising a frame supporting said processing chambers and said vacuum pump.

8. The system of claim 5, wherein another of said processing chambers is a thermal processing chamber including a second vacuum chamber including a second vacuum chamber including a second support, a second array of incandescent lamps disposed in a second sealed lamp chamber, a second window, and wherein said vacuum pump pumps said second sealed lamp chamber.

9. A multi-chamber processing system, comprising:
a factory interface operating at substantially atmospheric pressure and capable of mounting a plurality of substrate cassettes;
a plurality of substrate processing chambers connected to said factory interface through respective substrate ports and respective substrate valves disposed between said ports and said processing chambers; and
a robot mounted within said factory interface and including one or more blades capable of transferring substrates in and out of said plurality of substrate processing chambers and said substrate cassettes;
wherein the substrate port of at least one of said substrate processing chambers includes a gas port inert gas on a first lateral side wall of said port, a slit aperture formed in a second lateral side wall of said port opposite said first side wall and connected to a vacuum pump.

10. The system of claim 9, wherein a transfer axis along which said robot transfers substrates in and out of the substrate processing chamber including said substrate port passes between said gas port and said slit.

11. A method of thermal processing, including the steps of:
at atomospheric pressure, transferring a substrate through a slit valve to a support in a processing volume of thermal processing chamber;
closing said slit valve and vacuum pumping said chamber;
flowing a first process gas into said chamber;
irradiating said substrate on said support with an array of incandescent lamps in a lamp chamber separated from processing volume by a window to heat said substrate supported on said support to an elevated first temperature while said processing volume is maintained at a first reduced pressure; and
maintaining said lamp chamber at a reduced pressure differing from said first reduced pressure by no more than 5 Torr.

12. The method of claim 11, further comprising flowing a thermal transfer gas into said lamp chamber.

13. The method of claim 12, wherein said thermal transfer gas comprises helium.

14. The method of claim 11, further comprising the subsequent steps of:
flowing a second process gas different from said first process gas into said chamber;
irradiating said substrate on said support with said array of incandescent lamps to heat said substrate supported on said support to an elevated second temperature different from said first temperature while said processing volume is maintained at a second reduced pressure different from said first reduce pressure; and
maintaining said lamp chamber at a reduced pressure differing from said second reduced pressure by no more than 5 Torr.
